(19) United States
(12) Patent Application Publication
(10) Pub. No.: US 2026/0005489 A1
(43) Pub. Date: Jan. 1, 2026

(54) MULTI-EMITTER LASER DEVICE STRUCTURES

(71) Applicant: KYOCERA SLD Laser, Inc., Goleta, CA (US)

(72) Inventors: Christian Zollner, Santa Barbara, CA (US); Phillip Skahan, Santa Barbara, CA (US); Changmin Lee, Santa Barbara, CA (US)

(73) Assignee: KYOCERA SLD Laser, Inc., Goleta, CA (US)

(21) Appl. No.: 18/754,914

(22) Filed: Jun. 26, 2024

Related U.S. Application Data
(63) Continuation-in-part of application No. 17/849,848, filed on Jun. 27, 2022, now Pat. No. 12,464,802.

(51) Int. Cl. H01S 5/042; H01S 5/02355; H01S 5/12; H01S 5/22; H01S 5/40

(52) U.S. Cl. CPC H01S 5/0421; H01S 5/02355; H01S 5/12; H01S 5/22; H01S 5/4031

(57) ABSTRACT

A laser device structure on a carrier substrate, a bonding material overlying the carrier substrate, an epitaxial region overlying the bonding material, a plurality of p-contacts disposed between a first surface of the epitaxial region and the bonding material, trenches extending on either side of and along longitudinal sides of each p-contact of the plurality of p-contacts, and a plurality of n-contacts disposed on a second surface of the epitaxial material opposite the first surface.

### BACKGROUND

Direct diode lasers have been in existence for the past few decades, beginning with laser diodes based on the GaAs material system, then moving to the AlGaAsP and InP material systems. More recently, lasers based on GaN operating in the short wavelength visible regime have become of great interest. More specifically, laser diodes operating in the violet, blue, and green regimes are attracting attention due to the increased range of applications compared with GaAs laser diodes. Conventional GaN based laser diodes placed in a multi-emitter array have a number of applications including for optical storage, display, and other applications, but unfortunately, the device performance is often inadequate.

### SUMMARY

The present invention provides methods and devices for laser device structures including multi-emitter laser diode structures.

In a specific embodiment, a laser device structure includes a carrier substrate. The structure also includes a bonding material overlying the carrier substrate. The structure also includes an epitaxial region overlying the bonding material, the epitaxial region may include at least one active region, the epitaxial region having a different composition than the carrier substrate. The structure also includes a p-contact disposed between a first surface of the epitaxial region and the bonding material. The structure also includes trenches extending along longitudinal sides of the p-contact, where the trenches are at least partially filled with a dielectric material, where the first surface of the epitaxial region between the trenches is adjacent to the p-contact and the first surface of the epitaxial region outside the trenches is adjacent to the bonding material, and where the first surface of the epitaxial region between the trenches is substantially co-planar with the first surface of the epitaxial region outside the trenches. The structure also includes an n-contact disposed on a second surface of the epitaxial material opposite the first surface.

Implementations may include one or more of the following features. The laser device structure where the trenches extend into the at least one active region of the epitaxial region. The trenches terminate without extending into the at least one active region of the epitaxial region. The epitaxial region may include a distributed-feedback (DFB) structure or a distributed bragg reflector (DBR) structure adjacent to the n-contact.

In accordance with another embodiment, a laser device structure includes a carrier substrate. The structure also includes a bonding material overlying the carrier substrate. The structure also includes an epitaxial region overlying the bonding material, the epitaxial region may include at least one active region, the epitaxial region having a different composition than the carrier substrate. The structure also includes a plurality of p-contacts disposed between a first surface of the epitaxial region and the bonding material. The structure also includes trenches extending along longitudinal sides of each p-contact of the plurality of p-contacts, where the trenches extend from the first surface into the epitaxial region and are at least partially filled with a dielectric material, where the first surface of the epitaxial region between a first trench and a second trench is adjacent to a first p-contact, the first surface of the epitaxial region between the second trench and a third trench is adjacent to the bonding material, and the first surface of the epitaxial region between the third trench and a fourth trench is adjacent to a second p-contact, where the first trench, the second trench, the third trench, and the fourth trench are sequential trenches, and where the first surface of the epitaxial region is substantially planar. The structure also includes a plurality of n-contacts disposed on a second surface of the epitaxial material opposite the first surface, where adjacent ones of the plurality of n-contacts are separated by isolation trenches, the isolation trenches extending into the epitaxial material from the second surface of the epitaxial material.

Implementations may include one or more of the following features. The laser device structure may include: an insulating layer overlying the plurality of n-contacts and at least partially filling the isolation trenches; and a plurality of metal lines overlying the insulating layer, where each metal line contacts one of the n-contacts through a via in the insulating layer. The trenches extend into the at least one active region of the epitaxial region. Each of the plurality of p-contacts and associated epitaxial region form an individually addressable emitter. The first trench and the second trench are bounded on the second surface of the epitaxial material by adjacent isolation trenches. One of the isolation trenches on the second surface of the epitaxial material is disposed between the second trench and the third trench. Each of the trenches are spatially aligned with an edge of an associated one of the p-contacts. The trenches are partially filled with the bonding material. The first surface of the epitaxial region is planar. A first portion of the epitaxial region between the first trench and the second trench forms a first emitter, and a second portion of the epitaxial region between the third trench and the fourth trench forms a second emitter. Each of the plurality of p-contacts is immediately adjacent to the bonding material. Each of the plurality of n-contacts is immediately adjacent to an insulating layer. The metal ground plate is coupled to a ground plane that provides electrical coupling to the plurality of p-contacts. Each metal line contacts one of the n-contacts through a via in the first insulating layer; a second insulating layer overlying the first insulating layer so that the metal lines extend between the first insulating layer and the second insulating layer; and an electrically conductive ground plate extending over the second insulating layer. The electrically conductive ground plane is coupled to the electrically conductive ground plate.

Of course, there can be other variations, modifications, and alternatives. A further understanding of the nature and advantages of the embodiments described herein may be realized by reference to the latter portions of the specification and attached drawings.

### BRIEF DESCRIPTION OF THE DRAWINGS

FIG. 1 is a simplified diagram illustrating an optical device according to an embodiment.

FIG. 2 is a cross-sectional view of a laser device according to an embodiment.

FIG. 3 is a simplified diagram illustrating a laser device having a plurality of emitters according to an embodiment.

FIG. 4 is a simplified diagram illustrating a front view of a laser device with multiple cavity members according to an embodiment.

FIGS. 5A and 5B are diagrams illustrating a laser package having “p-side” facing up according to an embodiment.

FIGS. 6A and 6B are simplified diagram illustrating a laser package having “p-side” facing down according to an embodiment.

FIG. 7 is a simplified diagram illustrating an individually addressable laser package according to an embodiment.

FIG. 8 is a simplified diagram illustrating a laser bar having a patterned bonding substrate according to an embodiment.

FIGS. 9a-9b are simplified illustrations of a die expanded laser diode according to an embodiment.

FIG. 10 is a top view of a selective area bonding process in an example.

FIG. 11 is a simplified process flow for epitaxial preparation in an example.

FIG. 12 is a simplified side view illustration of selective area bonding in an example.

FIG. 13 is a simplified process flow of epitaxial preparation with active region protection in an example.

FIG. 14 is a simplified process flow of epitaxial preparation with active region protection and with ridge formation before bonding in an example.

FIG. 15 schematically illustrates the geometrical relationship between the individual laser stripes on the epitaxial wafer prior to transfer to the carrier wafer according to an embodiment.

FIG. 16 is a simplified top view of a selective area bonding process and illustrates a die expansion process via selective areas bonding, resulting in a multiple-emitter laser device according to an embodiment.

FIG. 17 shows schematic diagrams of layouts for laser chips containing multiple die which will be individually addressable according to some embodiments.

FIG. 18 shows schematic diagrams of the layout for laser chips including metallic through vias containing multiple die which will be individually addressable according to other embodiments.

FIG. 19 shows schematic diagrams of the layout for laser chips containing multiple die which will be individually addressable according to some embodiments.

FIGS. 20a-20f are simplified cross-sectional diagrams illustrating formation of a mesa structure that can include 1 to N emitters in accordance with an embodiment.

FIGS. 21a-21f are simplified cross-sectional diagrams illustrating transfer of the mesa structure of FIG. 20f to a carrier substrate and subsequent processing to form a laser device structure in accordance with an embodiment.

FIGS. 22a-22b are simplified perspective and plan view diagrams of a multi-emitter laser device structure on a carrier substrate in accordance with an embodiment.

FIGS. 23a-23b are simplified plan and cross-sections diagrams of a multi-emitter laser device structure on a carrier substrate in accordance with another embodiment.

### DETAILED DESCRIPTION

Embodiments described herein provide GaN-based laser devices and related methods for making and using these laser devices.

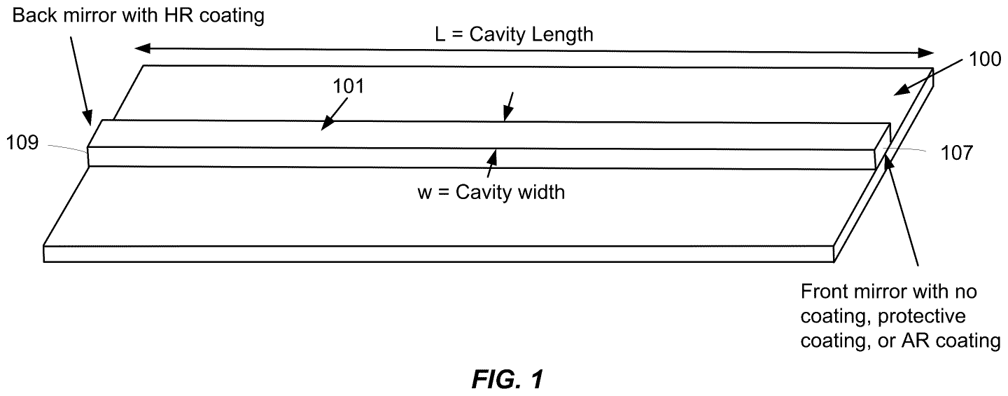

FIG. 1 is a simplified diagram illustrating an optical device. As an example, the optical device includes a gallium nitride substrate member 100 having a crystalline surface region characterized by a polar, semipolar or nonpolar orientation. For example, the gallium nitride substrate member may be a bulk GaN substrate characterized by having a polar, nonpolar or semipolar crystalline surface region, but can be others. The nitride crystal may comprise AlₓIn_{y}Ga_{1-x-y}N, where 0≤x, y, x+y≤1. In one specific embodiment, the nitride crystal comprises GaN. In some embodiments, the GaN substrate is characterized by a nonpolar orientation (e.g., m-plane), where waveguides are oriented in the c-direction or substantially orthogonal to the a-direction.

In certain embodiments, the device has a laser stripe region formed overlying a portion of the surface region. For example, the laser stripe region may be characterized by a cavity orientation substantially in a projection of a c-direction, which is substantially normal to an a-direction. In a specific embodiment, the laser strip region has a first end 107 and a second end 109. In an embodiment, the device is formed on a projection of a c-direction on a {20-21} gallium and nitrogen containing substrate having a pair of cleaved or etched mirror structures that face each other.

In an embodiment, the device has a first facet provided on the first end of the laser stripe region and a second facet provided on the second end of the laser stripe region. In one or more embodiments, the first facet is substantially parallel with the second facet. In other embodiments, the first facet may be angled relative to the second facet. Mirror surfaces may be formed on each of the facets. The first facet may comprise a first mirror surface having a reflective coating. The reflective coating may be selected from silicon dioxide, hafnia, and titania, tantalum pentoxide, zirconia, including combinations, and the like.

Also in an embodiment, the second facet may comprise a second mirror surface having an anti-reflective coating.

In a specific embodiment on a nonpolar Ga-containing substrate, the device is characterized by a spontaneously emitted light that is polarized substantially perpendicular to the c-direction. In an embodiment, the spontaneously emitted light is characterized by a polarization ratio of greater than 0.1 to about 1 perpendicular to the c-direction. In a preferred embodiment, the spontaneously emitted light may be characterized by a wavelength ranging from about 430 nanometers to about 470 nm to yield a blue emission, or about 500 nanometers to about 540 nanometers to yield a green emission, and others. For example, the spontaneously emitted light can be violet (e.g., 395 to 420 nanometers), blue (e.g., 430 to 470 nm); green (e.g., 500 to 540 nm), or others. In an embodiment, the spontaneously emitted light is highly polarized and is characterized by a polarization ratio of greater than 0.4. In another specific embodiment on a semipolar {20-21} Ga-containing substrate, the device is also characterized by a spontaneously emitted light is polarized in substantially parallel to the a-direction or perpendicular to the cavity direction, which is oriented in the projection of the c-direction.

In a specific embodiment, the present invention provides an alternative device structure capable of emitting 501 nm and greater wavelength light in a ridge laser embodiment. The device may be provided with one or more of the following epitaxially grown elements:
an n-GaN cladding layer with a thickness from 100 nm to 3000 nm with Si doping level of 5E17 to 3E18 cm−3;
an n-side SCH layer comprised of InGaN with molar fraction of indium of between 2% and 10% and thickness from 20 to 200 nm;
multiple quantum well active region layers comprised of at least two 2.0-8.5nm InGaN quantum wells separated by 1.5nm and greater, and optionally up to about 12nm, GaN or InGaN barriers;
a p-side SCH layer comprised of InGaN with molar a fraction of indium of between 1% and 10% and a thickness from 15 nm to 100 nm or an upper GaN-guide layer;
an electron blocking layer comprised of AlGaN with molar fraction of aluminum of between 6% and 22% and thickness from 5 nm to 20 nm and which may be doped with Mg;
a p-GaN cladding layer with a thickness from 400 nm to 1000 nm with Mg doping level of 2E17cm−3 to 2E19 cm−3;
a p++-GaN contact layer with a thickness from 20 nm to 40 nm with Mg doping level of 1E19cm−3 to 1E21 cm−3.

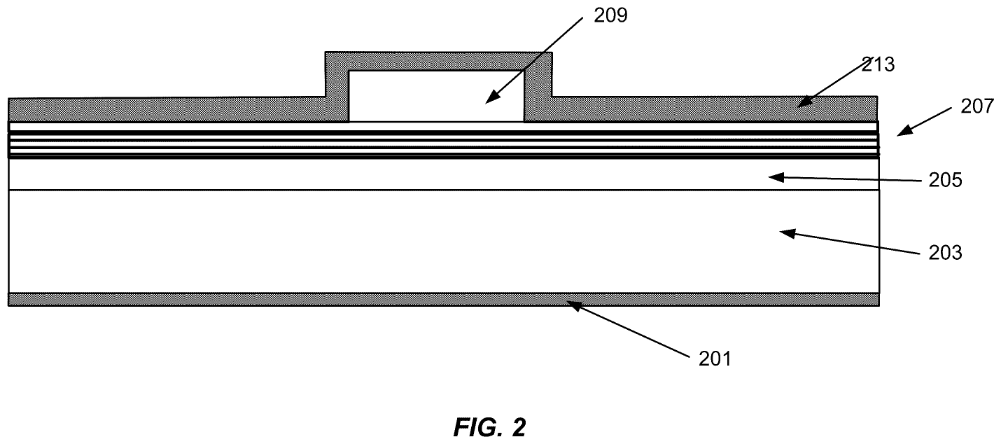

FIG. 2 is a cross-sectional view of a laser device. As shown, the laser device includes gallium nitride substrate 203, which has an underlying n-type metal back contact region 201. For example, the substrate 203 may be characterized by a polar, semipolar or nonpolar orientation. The device also has an overlying n-type gallium nitride layer 205, an active region 207, and an overlying p-type gallium nitride layer structured as a laser stripe region 209. Each of these regions is formed using at least an epitaxial deposition technique of metal organic chemical vapor deposition (MOCVD), molecular beam epitaxy (MBE), or other epitaxial growth techniques suitable for GaN growth. The epitaxial layer is a high-quality epitaxial layer overlying the n-type gallium nitride layer. In some embodiments the high-quality layer is doped, for example, with Si or O to form n-type material, with a dopant concentration between about 10¹⁶ cm⁻³ and 10²⁰ cm⁻³ .

An n-type AlᵤInᵥGa₁₋ᵤ₋ᵥN layer, where 0≤u, v, u+v≤1, is deposited on the substrate. The carrier concentration may lie in the range between about 10¹⁶ cm⁻³ and 10²⁰ cm⁻³ . The deposition may be performed using metalorganic chemical vapor deposition (MOCVD) or molecular beam epitaxy (MBE).

In one embodiment, the laser stripe region 209 includes a p-type gallium nitride layer. The laser stripe is provided by a patterning process, which may be a dry etching process, but wet etching can be used. The dry etching process may be an inductively coupled process using chlorine bearing species or a reactive ion etching process using similar chemistries. The chlorine bearing species are commonly derived from chlorine gas or the like. The device also has an overlying dielectric region 213. The dielectric region may be etched to expose a contact region adjacent to the laser stripe region 209. The dielectric region is an oxide such as silicon dioxide or silicon nitride, and the contact region may be coupled to an overlying metal layer. The overlying metal layer is preferably a multilayered structure containing gold and platinum (Pt/Au) or nickel gold (Ni/Au).

Active region 207 preferably includes one to ten quantum well regions or a double heterostructure region for light emission. In an embodiment, following deposition of the n-type AlᵤInᵥGa₁₋ᵤ₋ᵥN layer to achieve a desired thickness, an active layer is deposited. The quantum wells may comprise InGaN with GaN, AlGaN, InAlGaN, or InGaN barrier layers separating them. In other embodiments, the well layers and barrier layers comprise Al_{w}InₓGa_{1-w-x}N and Al_{y}In_{z}Ga_{1-y-z}N, respectively, where 0≤w, x, y, z, w+x, y+z≤1, where w<u, y and/or x>v, z so that the bandgap of the well layer(s) is less than that of the barrier layer(s) and the n-type layer. The well layers and barrier layers may each have a thickness between about 1 nm and about 20 nm. The composition and structure of the active layer are chosen to provide light emission at a preselected wavelength. The active layer may be left undoped (or unintentionally doped) or may be doped n-type or p-type.

The active region can also include an electron blocking region, and a separate confinement heterostructure. The electron-blocking layer may comprise AlₛInₜGa₁₋ₛ₋ₜN, where 0≤s, t, s+t≤1, with a higher bandgap than the active layer, and may be doped p-type. In one specific embodiment, the electron blocking layer includes AlGaN. In another embodiment, the electron blocking layer includes an AlGaN/GaN super-lattice structure, comprising alternating layers of AlGaN and GaN, each with a thickness between about 0.2 nm and about 5 nm.

As noted, the p-type gallium nitride structure is deposited above the electron blocking layer and active layer(s). The p-type layer may be doped with Mg, to a level between about 10¹⁶ cm⁻³ and 10²² cm⁻³ , with a thickness between about 5 nm and about 1000 nm. The outermost 1-50 nm of the p-type layer may be doped more heavily than the rest of the layer, so as to enable an improved electrical contact. The device also has an overlying dielectric region 213, for example, silicon dioxide, which exposes the contact region.

The metal contact (not shown) may be made of suitable material such as silver, gold, aluminum, nickel, platinum, rhodium, palladium, chromium, or the like. The contact may be deposited by thermal evaporation, electron beam evaporation, electroplating, sputtering, or another suitable technique. In an embodiment, the electrical contact serves as a p-type electrode for the optical device. In another embodiment, the electrical contact serves as an n-type electrode for the optical device. The laser devices illustrated in FIGS. 1 and 2 and described above are typically suitable for relatively low-power applications.

The laser stripe length, or cavity length may range from 15 μm to 3000 μm and employ growth and fabrication techniques such as those described, for example, in U.S. Pat. No. 9,531,164; issued Dec. 27, 2016; U.S. Pat. No. 9,184,563; issued Nov. 10, 2015; and U.S. Pat. No. 9,379,525; issued Jun. 28, 2016; which are incorporated by reference herein. As an example, laser diodes may be fabricated on nonpolar or semipolar gallium containing substrates, where the internal electric fields are substantially eliminated or mitigated relative to polar c-plane oriented devices. It is to be appreciated that reduction in internal fields may enable more efficient radiative recombination. In other instances, depending on the desired wavelength and other factors, starting with a c-plane or polar substrate may be preferred.

One difficulty with fabricating high-power GaN-based lasers with wide cavity designs is a phenomenon where the optical field profile in the lateral direction of the cavity becomes asymmetric where there are local bright regions and local dim regions. Such behavior is often referred to as filamenting and can be induced by lateral variations in the index of refraction or thermal profile, which alters the mode guiding characteristics. Such behavior can also be a result of non-uniformities in the local gain/loss caused by non-uniform injection of carriers into the active region or current crowding where current is preferentially conducted through the outer regions of the laser cavity. That is, the current injected through the p-side electrode tends towards the edge of the etched p-cladding ridge/stripe required for lateral waveguiding, and then conducted downward where the holes recombine with electrons primarily near the side of the stripe. In some transfer processes described herein, a similar phenomenon may occur with current injected through the n-side electrode. Regardless of the cause, such filamenting or non-symmetric optical field profiles can lead to degraded laser performance as the stripe width is increased.

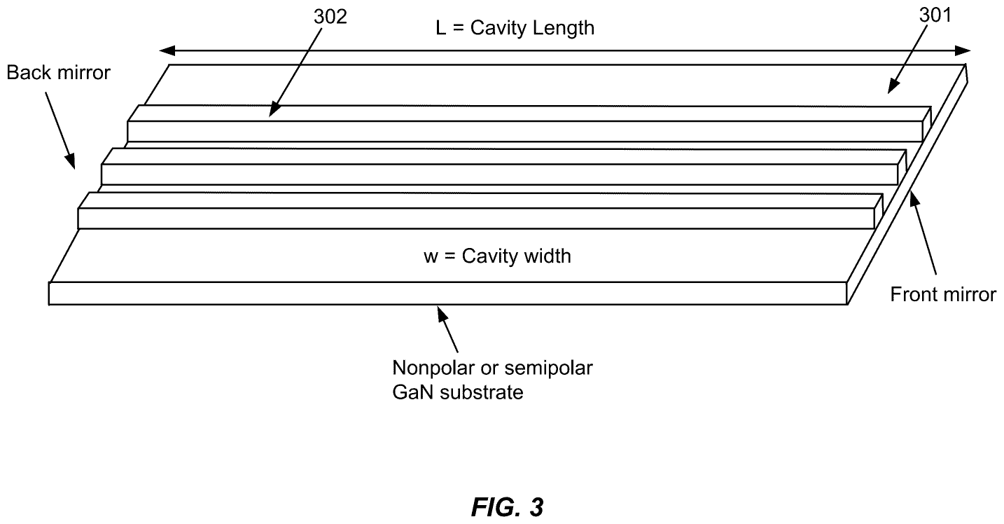

FIG. 3 is a simplified diagram illustrating a laser structure having a plurality of emitters according to an embodiment. As shown in FIG. 3, a laser structure includes a substrate and a plurality of emitters. Each cavity member, in conjunction with the accompanying active region and other electrical components, is a part of a laser diode. The laser structure in FIG. 3 includes three laser emitters, each having its emitter or cavity member (e.g., cavity member 302 functions a waveguide of a laser diode) and sharing the substrate 301, which contains one or more active regions. In various embodiments, the active regions include quantum wells or a double hetereostructure for light emission. The cavity members function as waveguides. A laser structure with multiple cavity members integrated on a single substrate and the method of manufacturing thereof are described in the U.S. Pat. No. 8,451,876; issued May 28, 2013, which is hereby incorporated by reference.

The substrate shown in FIG. 3 may contain gallium and nitrogen material fabricated from polar, nonpolar or semipolar bulk GaN substrate. The cavity members as shown are arranged in parallel to one another. For example, cavity member 302 includes a front mirror and a back mirror, similar to the cavity member 101 illustrated in FIG. 1. Each of the laser cavities may be characterized by a cavity width, w, ranging from about 1 to about 6 um. Such arrangement of cavity members increases the effective stripe width while assuring that the cavity members are uniformly pumped. In an embodiment, cavity members are characterized by a substantially equal length and width.

Depending on the application, a high-power laser device can have a number of cavity members. The number of cavity members, n, can range from 2 to 5, 10, or even 20 or more. The lateral spacing, or the distance separating one cavity member from another, in some embodiments can range from 2 um to 25 um, depending upon the requirements of the application. In various embodiments, the length of the cavity members can range from 300 um to 2000 um, an in some cases as much as 3000 um.

In an embodiment, laser emitters (e.g., cavity members as shown) are arranged as a linear array on a single chip to emit blue, green or red laser light. The emitters may be substantially parallel to one another, and they may be separated by 3 um to 15 um, by 15 um to 75 um, by 75 um to 150 um, or by 150 um to 300 um. The number of emitters in the array can vary from 3 to 15 or from 15 to 30, or from 30 to 50, or from 50 to 100, or more than 100. Each emitter may produce an average output power of 25 to 50 mW, 50 to 100 mW, 100 to 250 mW, 250 to 500 mW, 500 to 1000 mW, or greater than 1W. Thus the total output power of the laser device having multiple emitters can range from 200 to 500 mW, 500 to 1000 mW, 1-2 W, 2-5 W, 5-10 W, 10-20 W, and greater than 20 W.

With current technology, the dimension of the individual emitters may have widths of 1.0 to 3.0 um, 3.0 to 6.0um, 6.0 to 10.0um, 10 to 20.0 um, and greater than 20 um. The lengths range from 400 um to 800 um, 800 um to 1200 um, 1200 um to 1600 um, or greater than 1600 um.

The cavity member has a front end and a back end. The laser device is configured to emit laser beam through the front end. The front end can have anti-reflective coating or no coating at all, thereby allowing radiation to pass through the front end without excessive reflectivity. Since no laser beam is to be emitted from the back end of the cavity member, the back mirror is configured to reflect the radiation back into the cavity. For example, the back mirror may include highly reflective coating with a reflectivity greater than 85% or 95%.

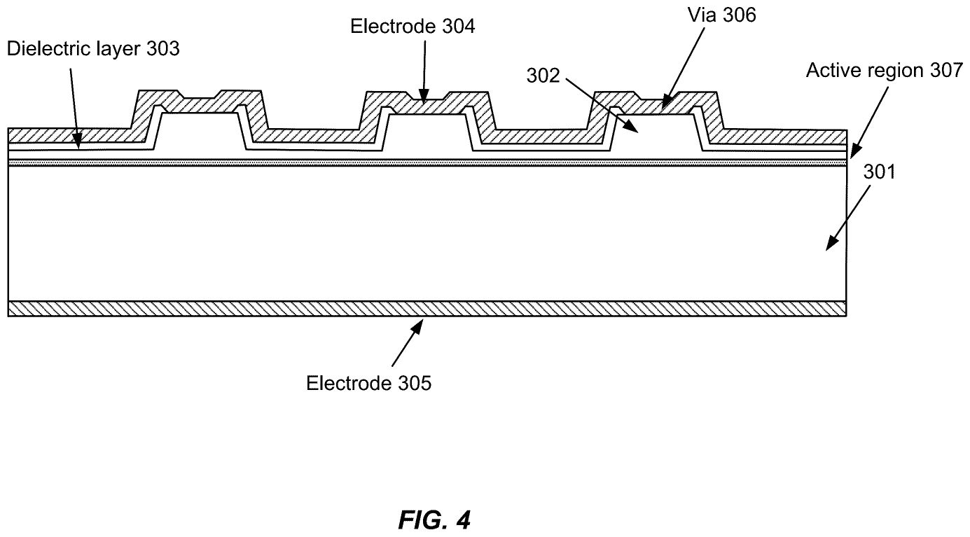

FIG. 4 is a simplified diagram illustrating a front view of a laser structure with multiple cavity members. As shown in FIG. 4, an active region 307 can be seen as positioned in the substrate 301. The cavity member 302 as shown includes a via 306. Vias are provided on the cavity members and opened in a dielectric layer 303, such as silicon dioxide. The top of the cavity members with vias can be seen as laser ridges, which expose electrode 304 for an electrical contact. The electrode 304 includes p-type electrode. In a specific embodiment, a common p-type electrode is deposited over the cavity members and dielectric layer 303, as illustrated in FIG. 4.

The cavity members are electrically coupled to each other by the electrode 304. The laser emitters, each having an electrical contact through its cavity member, share a common n-side electrode. Depending on the application, the n-side electrode can be electrically coupled to the cavity members in different configurations. In a preferred embodiment, the common n-side electrode is electrically coupled to the bottom side of the substrate. In certain embodiments, n-contact is on the top of the substrate, and the connection is formed by etching deep down into the substrate from the top and then depositing metal contacts. For example, laser emitters are electrically coupled to one another in a parallel configuration. In this configuration, when current is applied to the electrodes, all laser cavities can be pumped relatively equally. Further, since the ridge widths will be relatively narrow in the 1.0 to 5.0 um range, the center of the cavity member will be in close vicinity to the edges of the ridge (e.g., via) such that current crowding or non-uniform injection will be mitigated. Most importantly, filamenting can be prevented and the lateral optical field profile can be symmetric narrow cavities.

It is to be appreciated that the laser structure with multiple cavity members has an effective ridge width of n×w, which could easily approach the width of conventional high-power lasers having a width in the 10 to 50 um range. Typical lengths of this multi-stripe laser could range from 100 um to 2000 um, but they could be as much as 3000 um.

The laser structure illustrated in FIGS. 3 and 4 has a wide range of applications as a laser device. For example, the laser device can be coupled to a power source and operate at a power level of 0.5 to 10 W. In certain applications, the power source is specifically configured to operate at a power level of greater than 10 W. The operating voltage of the laser device can be less than 5V, 5.5V, 6V, 6.5V, 7V, and other voltages. In various embodiments, the wall plug efficiency (e.g., total electrical-to-optical power efficiency) can be 15% or greater, 20% or greater, 25% or greater, 30% or greater, 35% or greater.

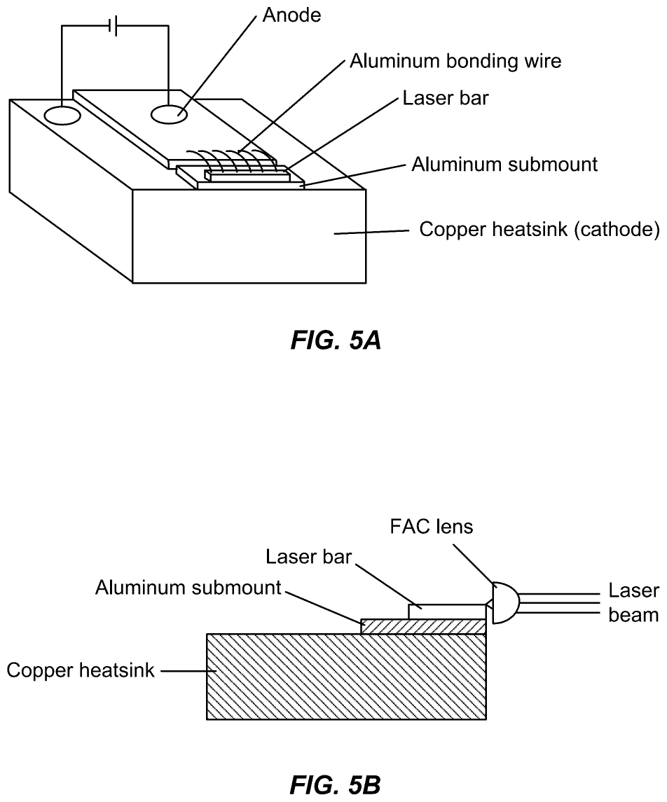

A typical application of laser devices is to emit a single ray of laser light. As the laser device includes a number of emitters, an optical member is needed to combine or collimate output from the emitters. FIGS. 5A and 5B are diagrams illustrating a laser package having “p-side” facing up. As shown in FIG. 5A, a laser bar is mounted on a submount. The laser bar includes an array of emitters (e.g., as illustrated in FIGS. 3 and 4). The laser bar is attached the submount, which is positioned between the laser bar and a heat sink. It is to be appreciated that the submount allows the laser bar (e.g., gallium nitride material) to securely attached to the heat sink (e.g., copper material with high thermal emissivity). In various embodiments, submount includes aluminum nitride material characterized by a high thermal conductivity. For example, thermal conductivity for aluminum nitride material used in the submount can exceed 200 W/(mk). Other types of materials can be used for submount as well, such as diamond, copper tungsten alloy, beryllium oxide. In an embodiment, the submount materials are used to compensate coefficient of thermal expansion (CTE) mismatch between the laser bar and the heat sink.

In FIG. 5A, the “p-side” (i.e., the side with emitters) of the laser bar faces upward and thus is not coupled to the submount. The p-side of the laser bar is electrically coupled to the anode of a power source through a number of bonding wires. Since both the submount and the heat sink are conductive, the cathode electrode of the power source can be electrically coupled to the other side of the laser bar through the submount and the heat sink.

In an embodiment, the array of emitters of the laser bar is manufactured from a gallium nitride substrate. The substrate can have surface characterized by a polar, semi-polar or non-polar orientation. The gallium nitride material allows the laser device to be packaged without hermetic sealing. More specifically, by using the gallium nitride material, the laser bar may be substantially free of AlGaN or InAlGaN claddings. When the emitter is substantially in proximity to p-type material, the laser device may be substantially free of p-type AlGaN or p-type InAlGaN material. Typically, AlGaN or InAlGaN claddings are unstable when operating in normal atmosphere, as they interact with oxygen. To address this problem, conventional laser devices comprising AlGaN or InAlGaN material are hermetically sealed to prevent interaction between AlGaN or InAlGaN and air. In contrast, since AlGaN or InAlGaN claddings may not be present in laser devices according to some embodiments, the laser devices do not need to be hermetically packaged. The cost of manufacturing laser devices and packages according to some embodiments can be lower than that of conventional laser devices by eliminating the need for hermetic packaging.

FIG. 5B is a side view diagram of the laser device illustrated in FIG. 5A. The laser bar is mounted on the submount, and the submount is mounted on the heat sink. As explained above, since the laser bar includes a number of emitters, a collimating lens may be used to combine the emitted laser to form a desired laser beam. In an embodiment, the collimating lens is a fast-axis collimating (FAC) lens that is characterized by a cylindrical shape.

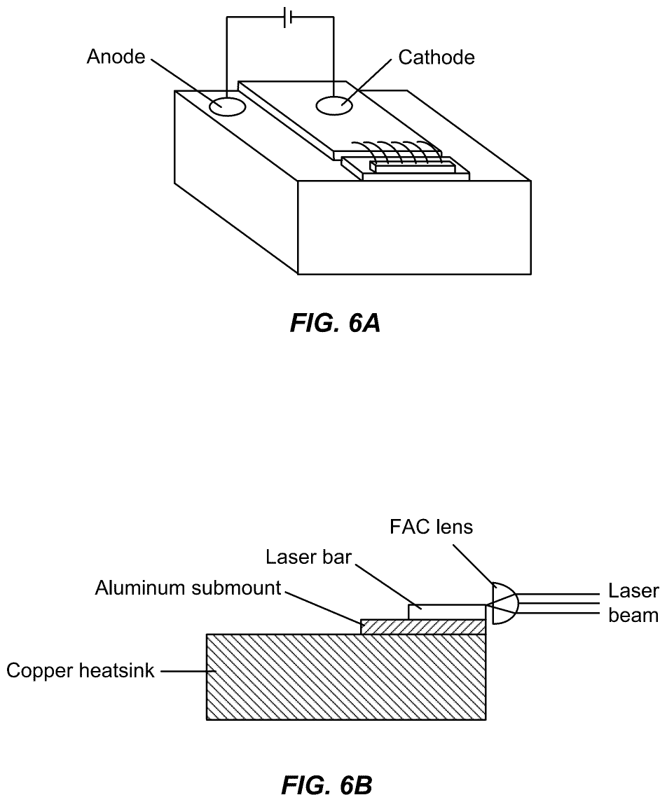

FIGS. 6A and 6B are simplified diagram illustrating a laser package having “p-side” facing down according to some embodiments. In FIG. 6A, a laser bar is mounted on a submount. The laser bar includes an array of emitters (e.g., as illustrated in FIGS. 3 and 4). In an embodiment, the laser bar includes substrate characterized by a polar, semipolar or non-polar orientation. The laser bar is attached the submount, which is positioned between the laser bar and a heat sink. The “p-side” (i.e., the side with emitters) of the laser bar faces down and thus is directly coupled to the submount. The p-side of the laser bar is electrically coupled to the anode of a power source through the submount and/or the heat sink. The other side of the laser bar is electrically coupled to the cathode of the power source through a number of bonding wires.

FIG. 6B is a side view diagram of the laser device illustrated in FIG. 6A. As shown, the laser bar is mounted on the submount, and the submount is mounted on the heat sink. As explained above, since the laser bar includes a number of emitters, a collimating lens may be used to combine the emitted laser to form a desired laser beam. In an embodiment, the collimating lens is a fast-axis collimating (FAC) lens that is characterized by a cylindrical shape.

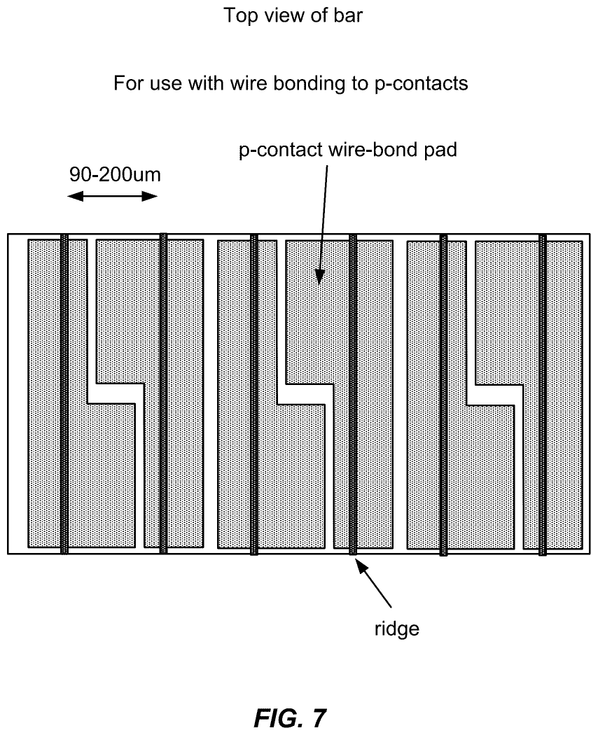

FIG. 7 is a simplified diagram illustrating an individually addressable laser package according to an embodiment. The laser bar includes a number of emitters separated by ridge structures. Each of the emitters is characterized by a width of about 90-200 um, but it is to be understood that other dimensions are possible as well. Each of the laser emitters includes a pad for p-contact wire bond. For example, electrodes can be individually coupled to the emitters so that it is possible to selectively turn an emitter on and off. The individually addressable configuration shown in FIG. 7 provides numerous benefits. For example, if a laser bar having multiple emitters is not individually addressable, laser bar yield during manufacturing can be a problem, since many individual laser devices need to be good in order for the bar to pass, and that means laser bar yield will be lower than individual emitter yield. In addition, setting up the laser bar with single emitter addressability makes it possible to screen each emitter. In certain embodiments, a control module is electrically coupled to the laser for individually controlling devices of the laser bar.

FIG. 8 is a simplified diagram illustrating a laser bar having a patterned bonding substrate according to an embodiment. As shown, laser devices may be characterized by a width of around 30 um. Depending on the application, other widths are possible as well. Laser emitters having pitches smaller than about 90 microns are difficult to form wire bonds. In various embodiments, a patterned bonding substrate is used for forming contacts. For example, the pattern bonding substrates allows for the width to be as low as 10-30 um or less.

In a specific embodiment, the laser device can be used in a variety of applications. The applications include power scaling (modular possibility), spectral broadening (select lasers with slight wavelength shift for broader spectral characteristics). The applications can also include multicolor monolithic integration such as blue-blue, blue-green, RGB (Red-Blue-Green), and others.

In some embodiments, a die expansion process may be used that can reduce manufacturing costs. In an example, a gallium and nitrogen containing substrate having a surface region may be provided for forming epitaxial material overlying the surface region, the epitaxial material comprising an n-type cladding region, an active region comprising at least one active layer overlying the n-type cladding region, and a p-type cladding region overlying the active region. The epitaxial material may be patterned to form a plurality of dies, each corresponding to at least one emitter or laser device, characterized by a first pitch between a pair of adjacent dies, the first pitch being less than a design width. At least some of the plurality of dies may be transferred to a carrier wafer such that each pair of adjacent transferred dies is configured with a second pitch larger than the first pitch and corresponding to the design width. Thus, the pitch between adjacent dies on the carrier wafer is expanded compared to the first pitch on the gallium and nitrogen containing substrate. The carrier wafer may be singulated into a plurality of emitters or laser diode devices on carrier chips. The carrier chips effectively serve as the submount of the emitter or laser diode device and can be integrated directly into a wide variety of package types.

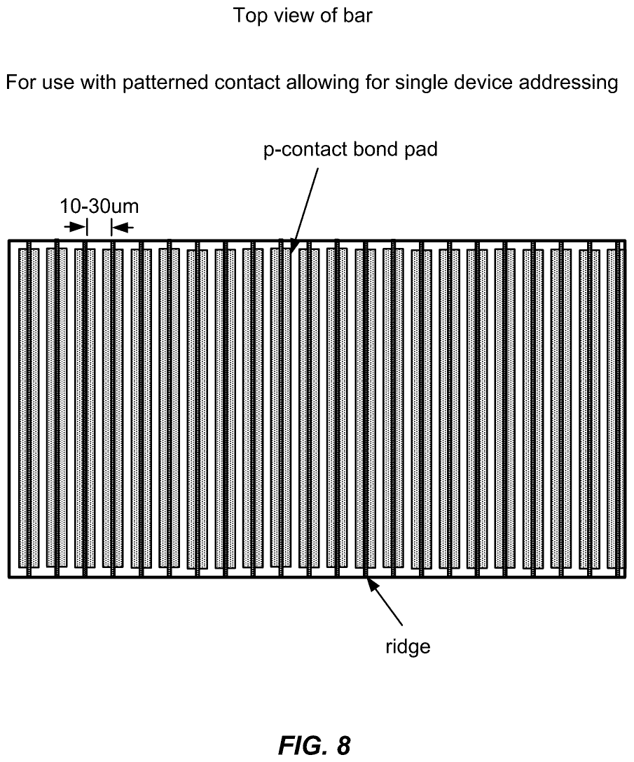

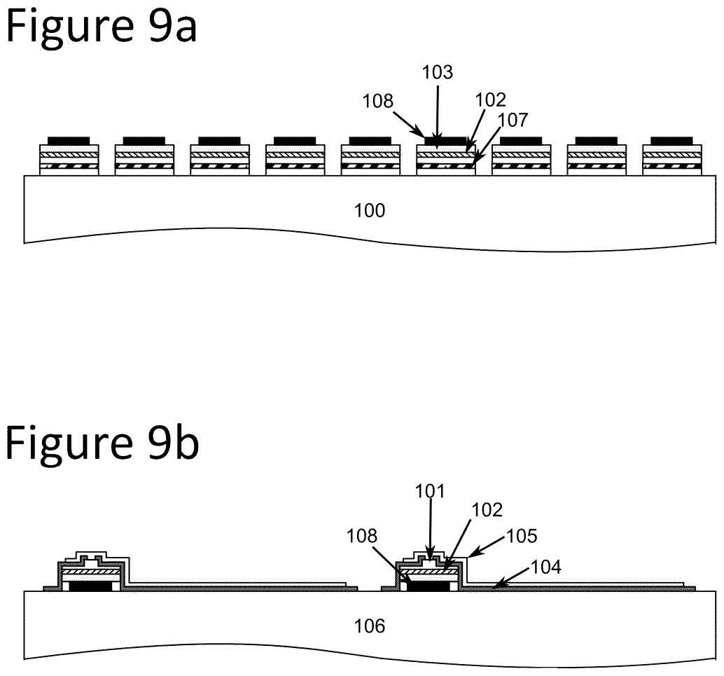

FIGS. 9a-9b are side view illustrations of a gallium and nitrogen containing epitaxial wafer 100 before the die expansion process and carrier wafer 106 after the die expansion process. This figure demonstrates a roughly five times expansion and thus five times improvement in the number of laser diodes, which can be fabricated from a single gallium and nitrogen containing substrate and overlying epitaxial material. Typical epitaxial and processing layers are included for example purposes and include n-GaN and n-side cladding layers 101, active region 102, p-GaN and p-side cladding 103, insulating layers 104, and contact/pad layers 105. Additionally, a sacrificial region 107 and bonding material 108 are used during the die expansion process.

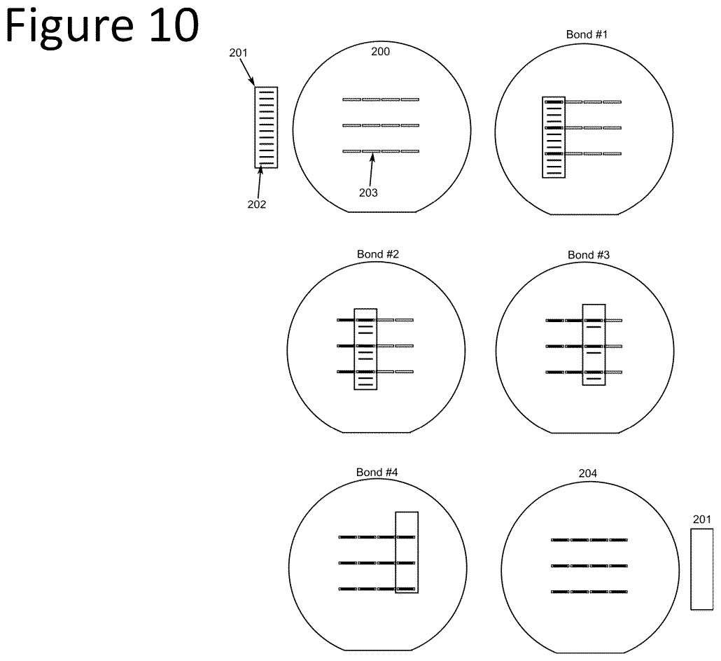

FIG. 10 is a simplified top view of a selective area bonding process and illustrates a die expansion process via selective area bonding. The original gallium and nitrogen containing epitaxial wafer 201 has had individual die of epitaxial material and release layers defined through processing. Individual epitaxial material die are labeled 202 and are spaced at pitch 1. A round carrier wafer 200 has been prepared with patterned bonding pads 203. These bonding pads are spaced at pitch 2, which is an even multiple of pitch 1 such that selected sets of epitaxial die can be bonded in each iteration of the selective area bonding process. The selective area bonding process iterations continue until all epitaxial die have been transferred to the carrier wafer 204. The gallium and nitrogen containing epitaxy substrate 201 can now optionally be prepared for reuse.

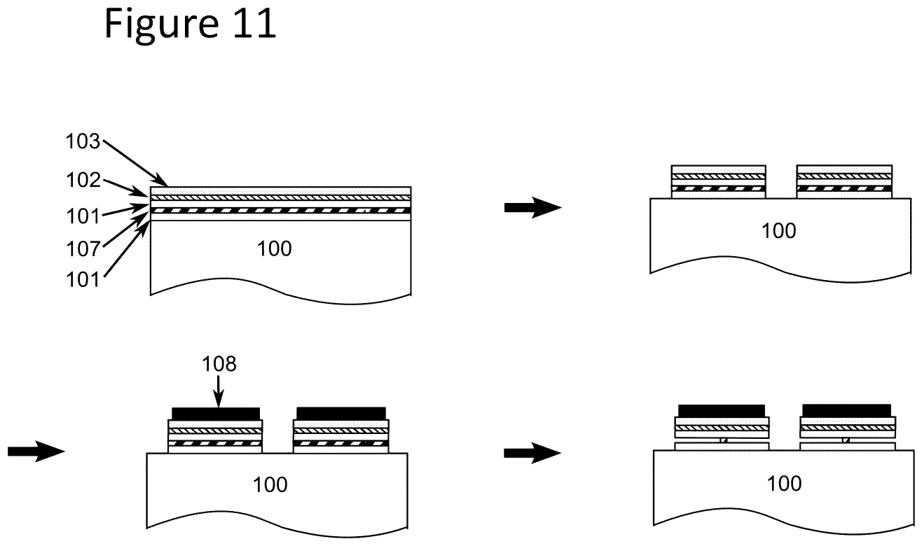

In an example, FIG. 11 is a simplified diagram of process flow for epitaxial preparation including a side view illustration of an example epitaxy preparation process flow for the die expansion process. The gallium and nitrogen containing epitaxy substrate 100 and overlying epitaxial material are defined into individual die, bonding material 108 is deposited, and sacrificial regions 107 are undercut. Typical epitaxial layers are included for example purposes and are n-GaN and n-side cladding layers 101, active region 102, and p-GaN and p-side cladding 103.

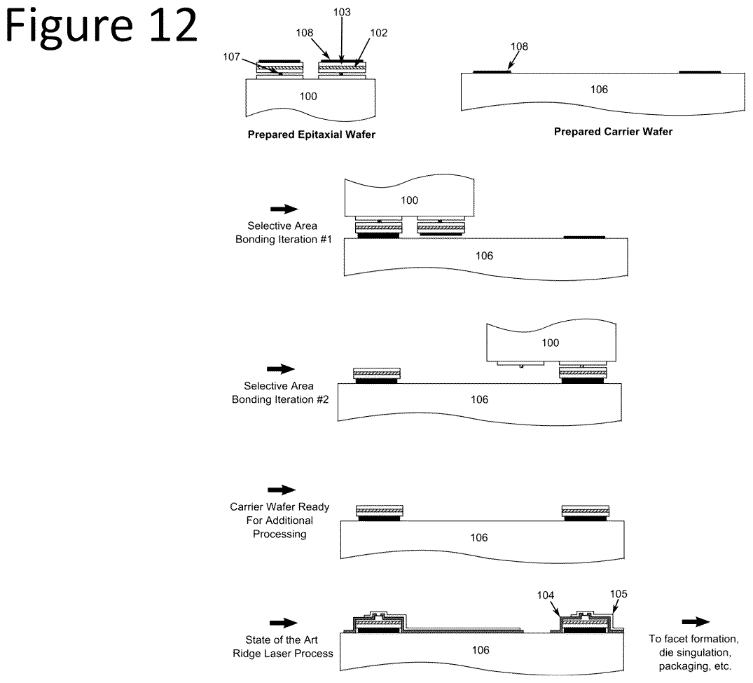

In an example, FIG. 12 is a simplified illustration of a side view of a selective area bonding process in an example. Prepared gallium and nitrogen containing epitaxial wafer 100 and prepared carrier wafer 106 are the starting components of this process. The first selective area bonding iteration transfers a fraction of the epitaxial die, with additional iterations repeated as needed to transfer all epitaxial die. Once the die expansion process is completed, state of the art laser processing can continue on the carrier wafer. Typical epitaxial and processing layers are included for example purposes and are n-GaN and n-side cladding layers 101, active region 102, p-GaN and p-side cladding 103, insulating layers 104 and contact/pad layers 105. Additionally, a sacrificial region 107 and bonding material 108 are used during the die expansion process.

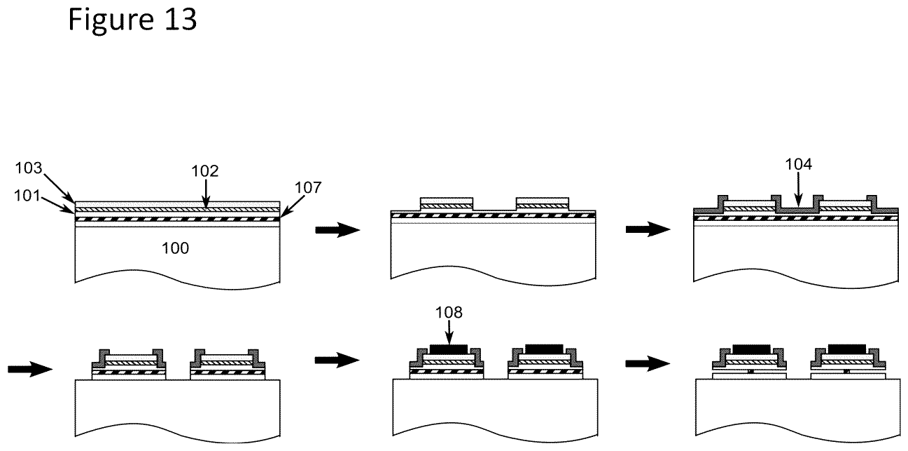

In an example, FIG. 13 is a simplified diagram of an epitaxy preparation process with active region protection. Shown is a side view illustration of an alternative epitaxial wafer preparation process flow during which sidewall passivation is used to protect the active region during any PEC undercut etch steps. This process flow allows for a wider selection of sacrificial region materials and compositions. Typical substrate, epitaxial, and processing layers are included for example purposes and are the gallium and nitrogen containing substrate 100, n-GaN and n-side cladding layers 101, active region 102, p-GaN and p-side cladding 103, insulating layers 104 and contact/pad layers 105. Additionally, a sacrificial region 107 and bonding material 108 are used during the die expansion process.

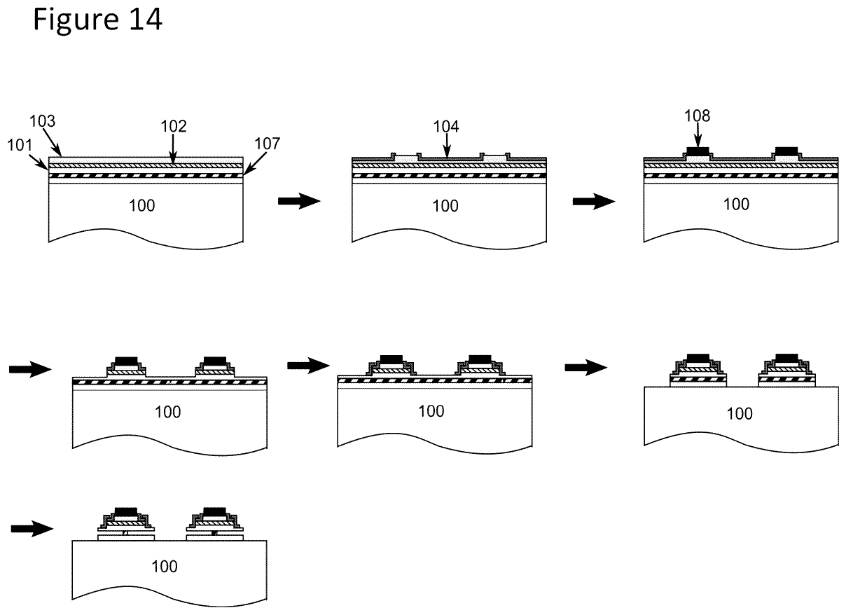

In an example, FIG. 14 is a simplified diagram of epitaxy preparation process flow with active region protection and ridge formation before bonding. Shown is a side view illustration of an alternative epitaxial wafer preparation process flow during which sidewall passivation is used to protect the active region during any PEC undercut etch steps and laser ridges are defined on the denser epitaxial wafer before transfer. This process flow potentially allows cost saving by performing additional processing steps on the denser epitaxial wafer. Typical substrate, epitaxial, and processing layers are included for example purposes and are the gallium and nitrogen containing substrate 100, n-GaN and n-side cladding layers 101, active region 102, p-GaN and p-side cladding 103, insulating layers 104 and contact/pad layers 105. Additionally, a sacrificial region 107 and bonding material 108 are used during the die expansion process.

Some embodiments enable significant improvements for improving the functionality and cost-efficiency of laser diodes, in particular, monolithically integrated devices containing more than one laser diode stripe onto a common substrate or carrier wafer such as a laser bar. In particular, the high cost of GaN substrates and epitaxy coupled with non-optimized yields associated with GaN-based lasers renders GaN laser bars to be uneconomical. With the present invention where epitaxial mesa regions are selectively transferred to a carrier wafer for fabrication of the multiple laser emitter the usage efficiency of the epitaxial area and gallium and nitrogen containing substrate is drastically increased such that the GaN based laser bars or multi-emitter laser devices can be manufactured economically. Several example advantages of multi-emitter devices according to this invention are listed below.
1. Optimal spacing of laser stripes which enable close spacing with minimal thermal cross-talk between the adjacent lasers stripes, while maintaining spacing close enough for common optical elements.
2. Enablement of series and series-parallel electrical connections between the laser stripes on a common substrate.
3. Individually addressable laser stripes.
4. Manufacturing processes with enhanced yield and lower cost.

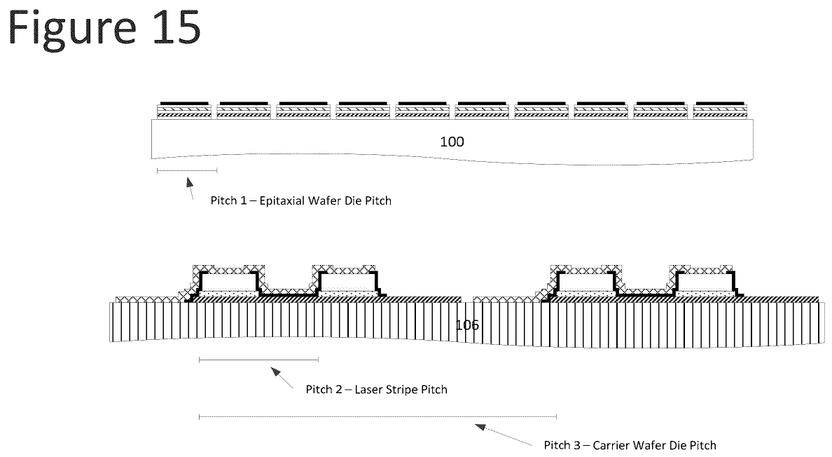

FIG. 15 schematically illustrates the geometrical relationship between the individual laser stripes on the epitaxial wafer prior to transfer to the carrier wafer, and the desired spacing between the multiple laser stripes on the carrier wafer following die transfer. The pitch between adjacent laser stripes on a single multiple-stripe laser, Pitch 2, must be an integer multiple, N, of the pitch between adjacent laser stripes on the epitaxial wafer, Pitch 1, where N≥1. The pitch between adjacent multiple-stripe lasers on a common carrier wafer, Pitch 3, must be an integer multiple, M, of the pitch between adjacent laser stripes on the epitaxial wafer, Pitch 1, where M>N.

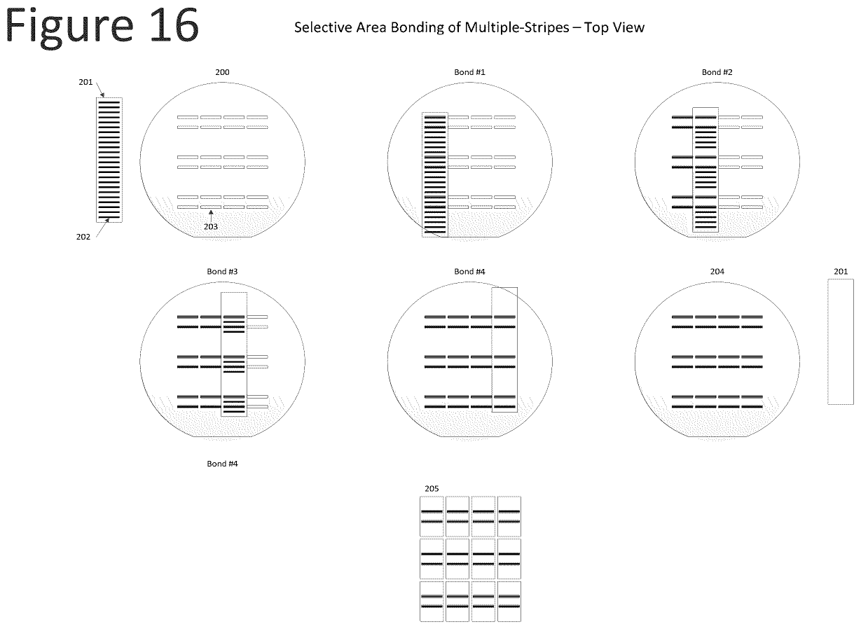

FIG. 16 is a simplified top view of a selective area bonding process and illustrates a die expansion process via selective areas bonding, resulting in a multiple-stripe laser. The original gallium and nitrogen containing epitaxial wafer 201 has had individual die of epitaxial material and release layers defined through processing. Individual epitaxial material die are labeled 202 and are spaced at pitch 1. A round carrier wafer 200 had been prepared with patterned bonding pads 203. These bonding pads are spaced at pitch 2, which is an even multiple of pitch 1 such that selected sets of epitaxial die can be bonded in each iteration of the selective area bonding process. The selective area bonding process iterations continue until all epitaxial die have been transferred to the carrier wafer 204. The carrier wafer is then singulated at pitch 3, resulting in a multitude of multiple-stripe lasers. The gallium and nitrogen containing epitaxy substrate 201 can now optionally be prepared for reuse.

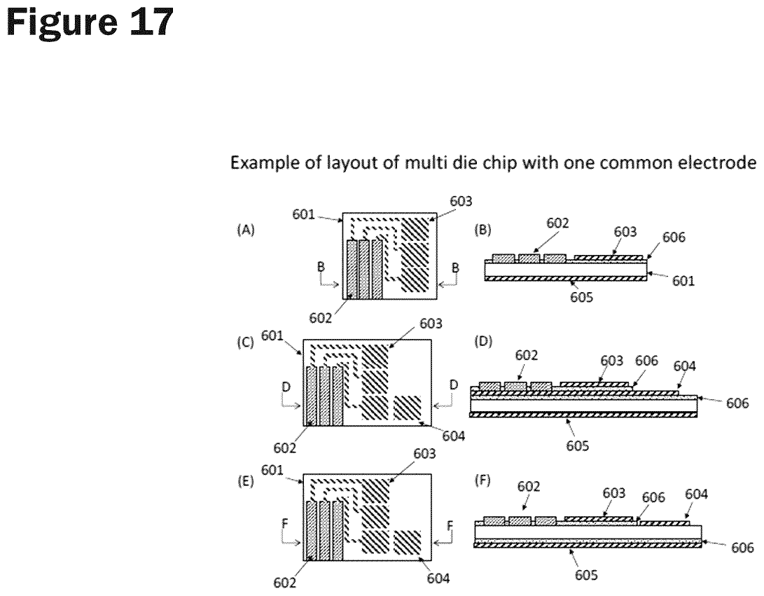

FIG. 17 shows schematics of the layout of three multi-die laser chips according to embodiments of this invention. Layout A and accompanying cross-section B show a laser chip comprised by a singulated piece of a carrier wafer 601, three laser die 602 transferred from epitaxial substrates, and metal traces and pads 603 for electrically connecting to the die. Layout A has the die bonded directly to the carrier wafer, which is both conductive and which forms a common electrode connected to a metal pad 605 on the backside of the carrier wafer. A passivating layer 606 is used to isolate the metal traces and pads 603 which contact the laser ridges and form the second electrode of the laser devices. The ridge side contacts are separate and electrically isolated from each other such that the laser devices may be run independently. Layout C and accompanying cross-section D show a similar structure, however the laser die are bonded to a metal layer 604 which is electrically isolated from the carrier wafer by passivation layers 606. A bond pad 605 is overlaid on the backside of the carrier wafer, providing a means to attach the laser chip to a submount, heat sink, printed circuit board or any other package. In this structure, the carrier wafer need not be conductive. Layout E and accompanying cross section F show a similar structure as layout C, however the carrier wafer is conductive and serves as a common electrode for the laser mesas. A passivation layer is deposited between the carrier and the backside bond pad 605 to electrically isolate the chip from the submount, heat sink, circuit board or other package type it is installed into.

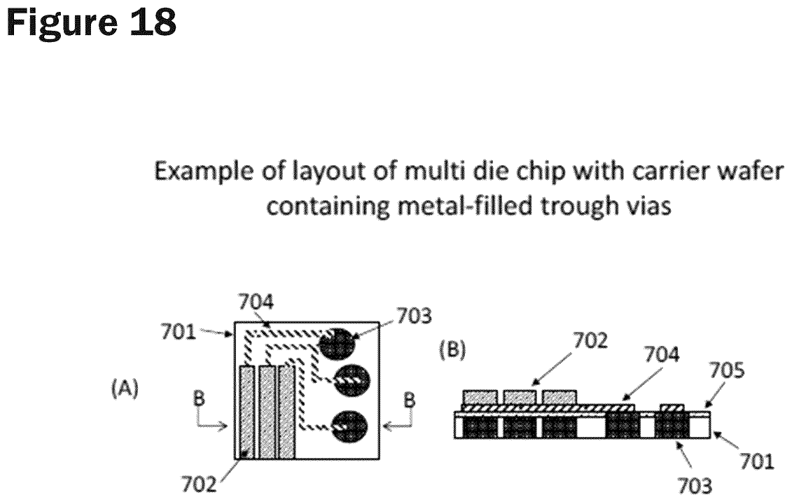

FIG. 18 shows schematics of the layout of a multi-die laser chips according to an embodiment of this invention. Layout A and accompanying cross-section B show a laser chip comprised by a singulated piece of a carrier wafer 701, three laser die 702 transferred from epitaxial substrates, and metal traces and conductive through vias 703 for electrically connecting to the die. The through vias penetrate through the carrier wafer and may be covered by bond pads which are not shown. The laser die are bonded to the carrier via a common electrode 704, however the ridge side contacts to the laser devices are electrically isolated from the common electrode metal and are connected to through vias that are isolated from the common electrode. A passivation layer 705 isolates the laser die and common electrode from metal filled through vias located beneath the die which provide a region higher thermal conductivity beneath the dies to facilitate heat extraction, but which are electrically isolated from laser die. In this embodiment, the carrier wafer must be electrically insulating.

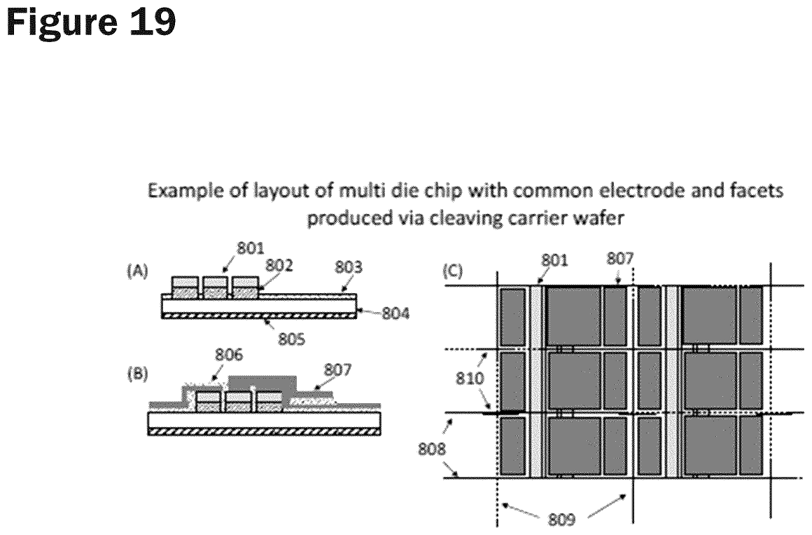

FIG. 19 shows schematics of the layout and fabrication of a multi-die laser chip according to an embodiment of this invention. Layout A shows the chip after bonding of the die, but before singulation and fabrication of the laser devices. Laser die 801 are bonded to the carrier wafer 804 via bond pads 802. The carrier wafer is electrically conductive and acts as a common electrode. A bond pad 805 is overlaid on the backside of the carrier wafer to provide a means of attaching the chip to a heat sink, submount or package, as well as to provide a means of electrically connecting to the device. A passivation layer 803 separates the carrier wafer from conductive layers 807 that make electrical contact to devices on individual laser die. A second passivation layer 806 is overlaid on the die and a conductive layer is overlaid on the second passivation layer to provide an electrically isolated electrical contact to the middle die. This arrangement allows bond pads to be formed which connect to the entire length of the laser ridge while being wide enough to be accessible with wire bonds. Plan view C shows part of the array of these devices fabricated on a carrier wafer. Lines 808 and 809 show the locations of cleaves used to singulate the carrier wafer into individual laser chips as well as form the front and back facets of the laser devices, where the facets may be cleaved or etched. Laser skip scribes 810 are used to provide guides for the cleaves. This configuration would require a single crystal carrier wafer in order to guide the cleave.

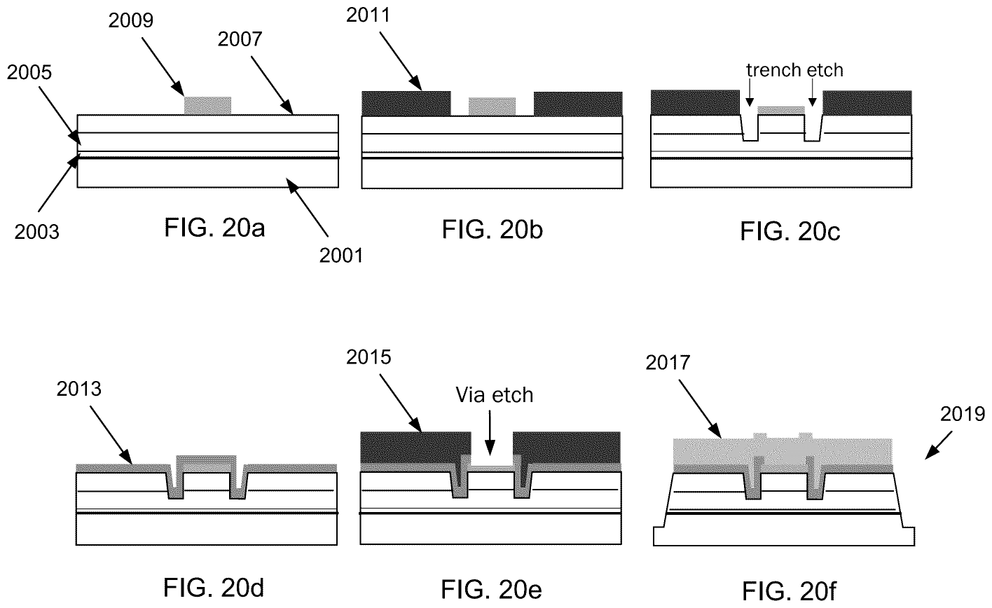

FIGS. 20a-20f are simplified cross-sectional diagrams illustrating formation of a laser device structure that can include 1 to N emitters in accordance with an embodiment. For ease of illustration, these figures illustrate the formation of a laser device structure having one emitter, but it should be appreciated that the structure can be replicated laterally to include N emitters depending on the particular application and spatial constraints. Examples of single-emitter structures include distributed-feedback (DFB) structures and distributed Bragg reflector (DBR) structures, examples of which can be found in U.S. patent application Ser. No. 18/228,633; filed Jul. 31, 2023; the contents of which are incorporated herein by reference. Examples of multi-emitter structures can be found in U.S. Pat. No. 9,595,813; issued Mar. 14, 2017; the contents of which are incorporated herein by reference. Features and processes described with regards to previous embodiments may be incorporated in the formation of the laser device structures shown and described in the following figures and detailed description.

FIG. 20a shows a substrate 2001 with an overlying epitaxial region that includes an active region 2005 and a p-side cladding 2007. Although not specifically shown, the epitaxial region may also include an n-side cladding and other layers and regions as described herein and as used in known laser device structures. This example also includes a sacrificial region 2003 and a p-contact 2009. In some embodiments, ridge length may be as short as 15 μm or less, and in other embodiments, individual emitters may be different lengths and/or widths.

While compositions of the layers and region may vary, in an embodiment, the substrate 2001 may comprise gallium and nitrogen, and the active region 2005 may comprise a quantum well structure having alternating quantum well and barrier regions. The sacrificial region 2003 may comprise InGaN or other materials as described in U.S. Pat. No. 9,520,697, the contents of which are incorporated herein by reference. The p-contact 2009 may comprise one or more of Ni, Pd, Pt, Ag among other materials. In some embodiments, the p-contact 2009 may be formed using known lift-off patterning techniques.

In FIG. 20b, a trench mask 2011 is formed and patterned using conventional photolithography techniques. Exposed portions of the p-side cladding 2007 are etched using known plasma or wet etch techniques to form trenches on each side of the p-contact 2009 as illustrated in FIG. 20c. The trenches may terminate above or within the active region 2005 in some embodiments or extend through the active region 2005 and into the n-side cladding in other embodiments. The trenches define an emitter region. The trenches may be self-aligned with the p-contact 2009 using the trench mask 2011 and p-contact 2009 as etch masks. In some embodiments, the trench mask 2011 may include photoresist, but materials other than the photoresist may be used with conventional deposition, photolithography, and etch techniques to form the trench mask 2011 on each side of the p-contact 2009 or even covering the p-contact 2009 while creating openings on each side for the trench etch.

In an alternative embodiment, the p-contact may be formed after trench formation using known deposition, patterning, and etch techniques. For example, the trenches may be formed and filled with a dielectric material, and a via may be etched between the trenches where the p-contact can be formed.

In FIG. 20d, the trench mask 2011 is removed and a liner 2013 is formed. The liner 2013 may comprise a dielectric such as silicon oxide in some embodiments. The liner 2013 may be formed using known dielectric film deposition processes such as plasma-enhanced chemical vapor deposition (PECVD) or atomic layer deposition (ALD) techniques. The liner 2013 is preferably formed onto the p-contact 2009 and trench-etched structures.

In FIG. 20e, a via mask 2015 is formed so that portions of the liner 2013 covering the p-contact 2009 can be removed. In some embodiments, the via mask 2015 may include photoresist, but materials other than the photoresist may be used with conventional deposition, photolithography, and etch techniques. The portions of the liner 2013 exposed by the via mask 2015 may be removed using known plasma or wet etch techniques to expose a surface of the p-contact 2009.

In FIG. 20f, a known etch process is used to form a mesa structure 2019. The mesa structure 2019 can include one or more emitters depending on a width of the mesa structure 2019 and a number of p-contacts 2009 and associated trenches that are included. The mesa structure 2019 is formed by etching sides of the structure to expose the sacrificial layer 2003. A bonding layer 2017 is also formed overlying the liner 2013 and p-contact 2009. The bonding layer 2017 may comprise a metal such as gold (Au) or another material as described in U.S. Pat. No. 9,520,697, the contents of which are incorporated herein by reference.

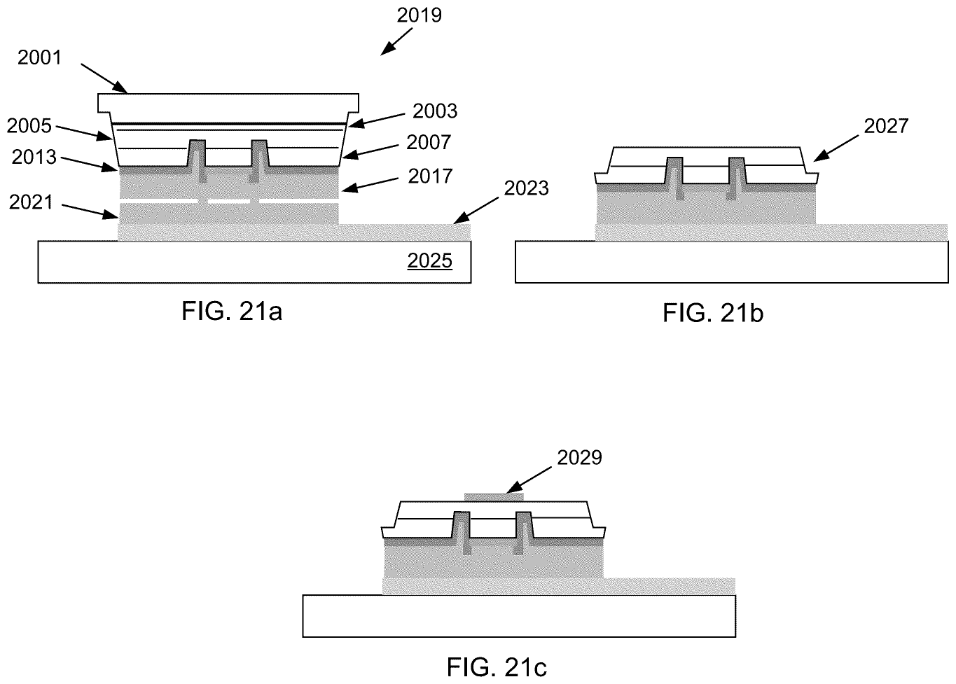

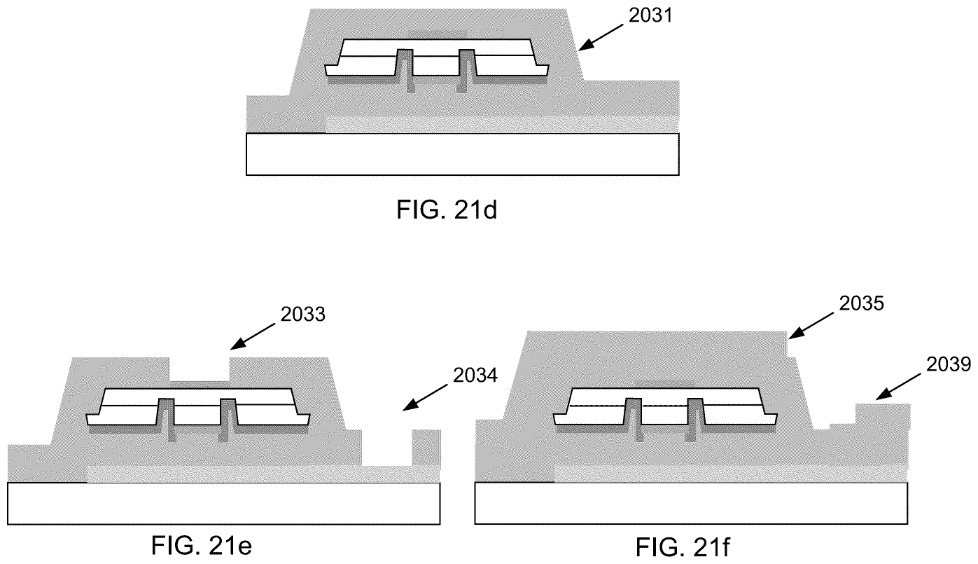

FIGS. 21a-21f are simplified cross-sectional diagrams illustrating transfer of the mesa structure 2019 of FIG. 20f to a carrier substrate 2025 and subsequent processing to form a laser device structure in accordance with an embodiment. The carrier substrate 2025 may comprise a different material than epitaxial region including the active region 2005 and the p-side cladding 2007. Further details on the carrier substrate 2025 may be found in U.S. Pat. No. 9,520,697, the contents of which are incorporated herein by reference.

In FIG. 21a, the bonding layer 2017 of the mesa structure 2019 is aligned with and coupled to a bonding layer 2021 of the carrier substrate 2025. The surface area of the bonding layer 2017 is substantially planar and provides a relatively large area for coupling between the bonding layer 2017 and the bonding layer 2021. The relatively large area is provided by the substantially planar surface of the p-side cladding 2007 that is adjacent to the bonding layer 2017 and the substantially planar surface of the p-contact 2009 that is adjacent to the bonding layer 2017. This structure also provides support for the mesa structure 2019 during the transfer process. In an embodiment, the bonding layers 2017, 2021 are processed to form a thermocompression bond as explained in U.S. Pat. No. 9,520,697, the contents of which are incorporated herein by reference. Other types of bonding processes can also be used. Although a gap is shown in FIG. 21a between the bonding layers 2017, 2021, the bonding layers 2017, 2021 are typically coupled by bonding so that the gap is reduced or eliminated before the substrate 2001 is removed from the mesa structure 2019.

As shown in FIG. 21b, the sacrificial layer 2003 and the substrate 2001 are removed so that remaining portions of the mesa structure 2019 are transferred to the carrier substrate 2025. The sacrificial layer 2003 may be removed, for example, using a PEC etch as described herein. Further details are included in U.S. Pat. No. 9,520,697, the contents of which are incorporated herein by reference. Note the “p-side” down configuration of the mesa structure 2019. The carrier substrate 2025 may include a contact 2023 for providing electrical coupling to the p-contact 2009 via the bonding layers 2017, 2021.

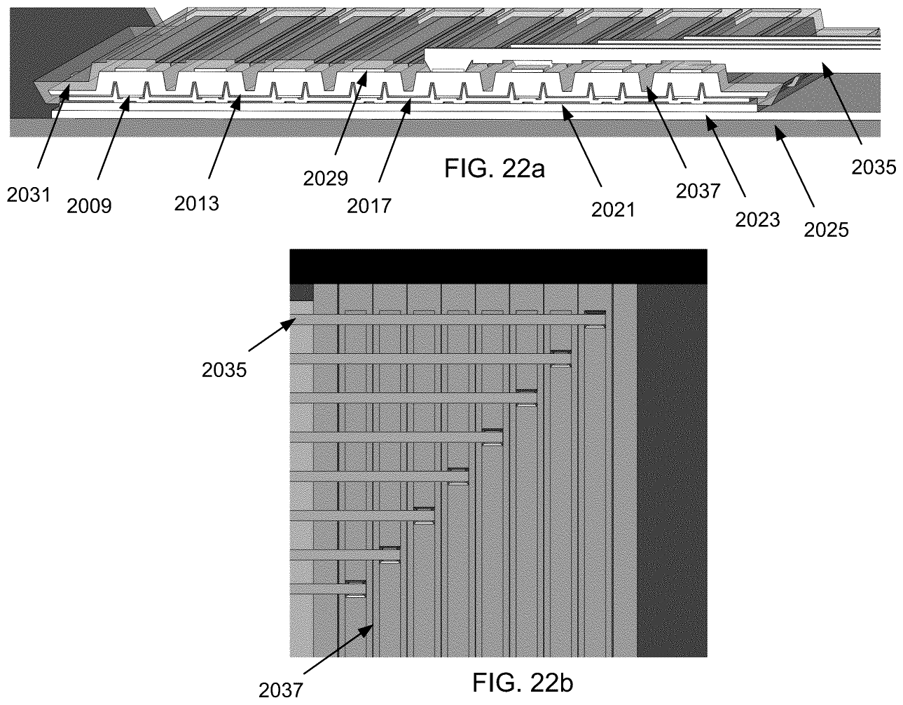

A trim process 2027 process may also be performed to prepare a profile of the mesa structure 2019 for subsequent processing. The trim process 2027 may be a known wet or dry etch process. The trim process 2027 may be used in multi-emitter embodiments to form isolation trenches 2037 between the emitters as shown in FIGS. 22a-22b. The isolation trenches 2037 may be filled with a dielectric and provide electrical isolation between the emitters.

In FIG. 21c, an n-contact 2029 is formed using known metal deposition and patterning techniques. The n-contact 2029 may comprise one or more of Ti, Al, Ni, Pd, Pt, Au, Ag among other conductive materials. In some embodiments, the n-contact 2029 may be formed using known lift-off patterning techniques.

In FIG. 21d, an insulating layer 2031 is formed using known deposition techniques. The insulating layer 2031 may fill the isolation trenches 2037 in multi-emitter embodiments (the insulating layer 2031 and isolation trenches 2037 are shown in FIG. 22a).

In FIG. 21e, photolithography and etch processes are used to form a via 2033 over the n-contact 2029 and a via 2034 over the contact 2023. In FIG. 21f, a metal line 2035 is deposited over the structure and provides electrical coupling to the n-contact 2029. A metal 2039 may also be deposited to provide electrical coupling to the p-contact 2009.

FIGS. 22a-22b are simplified perspective and plan view diagrams of a multi-emitter laser device structure on a carrier substrate in accordance with an embodiment. The multi-emitter laser device structure may be formed using the process described with regards to FIGS. 20-21. The multiple emitters are disposed on a carrier substrate 2025, and each of the multiple emitters include a p-contact 2009 electrically coupled to a contact 2023 via bonding layers 2017, 2021. A liner 2013 provides isolation between portions of a p-side cladding and the bonding layer 2017. An n-contact 2029 is formed adjacent to each emitter. Insulating layer 2031 covers the n-contacts 2029 and fills isolation trenches 2037 to provide isolation between the emitters and to provide isolation between the n-contacts 2029 and metal lines 2035. Each metal line 2035 is coupled to a corresponding one of the n-contacts 2029 through a via in the insulating layer 2031. By coupling individual metal lines 2035 to individual n-contacts 2029, individual emitter control can be implemented so that each emitter may be individually addressable. This allows the emitters to be individually turned on and off independent of other emitters in the same module.

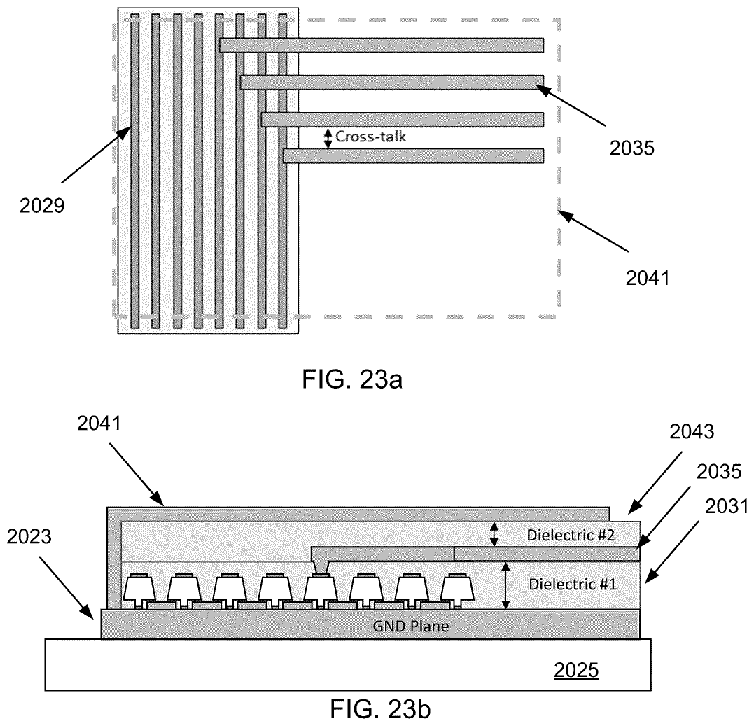

FIGS. 23a-23b are simplified plan and cross-sections diagrams of a multi-emitter laser device structure on a carrier substrate in accordance with another embodiment. FIG. 23a shows that cross-talk between adjacent metal lines 2035 can cause interference. A ground plate 2041 extending over a second insulating layer 2043 can reduce the interference. In some embodiments, the insulating layer 2031 may have a thickness of between about 1-2 μm, and the second insulating layer 2043 may be thinner than the insulating layer 2031. The ground plate 2041 and the second insulating layer 2043 can be formed, for example, by known deposition, patterning, and etching techniques. The ground plate 2041 may comprise one or more of Au, Ti, Ni, Pd, Pt, Ag among other conductive materials. The ground plate 2041 may be electrically coupled to the contact 2023. An area covered by the ground plate 2041 in an embodiment is shown by dotted lines in FIG. 23a. In some embodiments, the ground plate 2041 can cover the metal lines 2035.

The multi-emitter embodiments described herein may be used, for example, in micro-display applications such as liquid crystal on silicon (LCOS) displays. The micro-display applications may include augmented reality (AR), virtual reality (VR), mixed reality (MR), heads up display (HUD), and other systems. In some embodiments, the micro-display applications may include micro-electro-mechanical (MEMS) mirror laser-beam-scanning (LBS) designs. In other embodiments, the micro-display applications may include a photonic integrated circuit (PIC) or planar light-wave circuit (PLC) with waveguides for each emitted beam. The waveguides may be used to change pitch between emitted beams, to combine beams, and/or or to shape beams, such as to improve beam quality or to expand the beam into a larger area. In yet other embodiments, the multi-emitter modules may contain individually addressable emitters. The emitters may be configured to emit at wavelengths of 430 nm-480 nm, 510 nm-550 nm, 620 nm-670 nm, but can be others. In some embodiments, the lasers may be low power (e.g., 0.1 W or less) and emissions may be kept separate in the micro-display application. In other embodiments, an output of each laser may be combined and collimated within the module. In some embodiments, light emission from the emitters may be polarized to improve efficiency of the micro-display application.

Some multi-emitter embodiments may be packaged in customized ceramic packages (e.g., AlN packages) with or without heatsinking materials. Some embodiments may use high-speed packages having a large number of inputs and outputs (I/O's). The packages may be integrated with photodiodes, thermistors, amplifier transistor devices, and the like.

In other embodiments, the laser devices described herein can be configured on a variety of packages. As an example, the packages include surface mount device (SMD), TO9 Can, TO56 Can, flat package(s), CS-Mount, G-Mount, C-Mount, micro-channel cooled package(s), and others. In other examples, the multiple laser configuration can have an operating power of 1.5 Watts, 3, Watts, 6 Watts, 10 Watts, and greater. In an example, the optical device, including multiple emitters, are free from any optical combiners, which lead to inefficiencies. In other examples, optical combiners may be included and configured with the multiple emitter devices. Additionally, the plurality of laser devices (i.e., emitters) may be an array of laser device configured on non-polar, semi-polar or polar oriented GaN or any combination of these, among others.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and l is non-zero), non-polar GaN substrates (i.e., substrate material where the largest area surface is oriented at an angle ranging from about 80-100 degrees from the polar orientation described above towards an (h k l) plane wherein l=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k l) plane wherein l=0, and at least one of h and k is non-zero). Of course, there can be other variations, modifications, and alternatives.

In other examples, the device also has a micro-channel cooler thermally coupled to the substrate. The device also has a submount characterized by a coefficient of thermal expansion (CTE) associated with the substrate and a heat sink. The submount may be coupled to the substrate, and the submount may comprise aluminum nitride material, BeO, diamond, composite diamond, or combinations. In a specific embodiment, the substrate is glued onto a submount, the submount being characterized by a heat conductivity of at least 200 W/(mk). In a specific example, the number N of emitters can range between 3 and 15, 15 and 30, 30 and 50, and can be greater than 50. In other examples, each of the N emitters produces an average output power of 25 to 50 mW, produces an average output power of 50 to 100 mW, produces an average output power of 100 to 250 mW, produces an average output power of 250 to 500 mW, or produces an average output power of 500 to 1000 mW. In a specific example, each of the N emitters produces an average output power greater than 1 W. In an example, each of the N emitters is separated by 3 um to 15 um from one another or separated by 15 um to 75 um from one another or separated by 75 um to 150 um from one another or separated by 150 um to 300 um from one another.

The process described above with regard to FIGS. 20-21 may be used to form other structures that may be used with laser devices. For example, the process may be used to form integrated waveguides that may be coated with materials such as lithium niobate to provide effects that include second harmonic generation (SHG).

While the above is a full description of the specific embodiments, various modifications, alternative constructions, combinations, and equivalents may be used. Therefore, the above description and illustrations should not be taken as limiting the scope of the present invention which is defined by the appended claims.

1. A laser device structure comprising:
a carrier substrate;
a bonding material overlying the carrier substrate;
an epitaxial region overlying the bonding material, the epitaxial region comprising at least one active region, the epitaxial region having a different composition than the carrier substrate;
a p-contact disposed between a first surface of the epitaxial region and the bonding material, the p-contact at the bottom-side of an emitter ridge;
trenches extending on either side of and along longitudinal sides of the p-contact so as to define a width of the emitter ridge, wherein the trenches are at least partially filled with a dielectric material, wherein the first surface of the epitaxial region between the trenches is adjacent to the p-contact, and wherein the first surface of the epitaxial region between the trenches is substantially co-planar with the first surface of the epitaxial region outside the trenches; and
an n-contact disposed on a second surface of the epitaxial material opposite the first surface, the n-contact at the top-side of the emitter ridge.

2. The laser device structure of claim 1, wherein the trenches extend into the at least one active region of the epitaxial region.

3. The laser device structure of claim 1, wherein the trenches terminate without extending into the at least one active region of the epitaxial region.

4. The laser device structure of claim 1, wherein the epitaxial region includes a distributed-feedback (DFB) structure or a distributed Bragg reflector (DBR) structure adjacent to the n-contact.

5. A laser device structure of a plurality of emitters, comprising:
a carrier substrate;
a bonding material overlying the carrier substrate;
an epitaxial region overlying the bonding material, the epitaxial region comprising at least one active region, the epitaxial region having a different composition than the carrier substrate;
a plurality of p-contacts disposed between a first surface of the epitaxial region and the bonding material;
trenches extending along longitudinal sides of each p-contact of the plurality of p-contacts, wherein the trenches extend from the first surface into the epitaxial region and are at least partially filled with a dielectric material, wherein the first surface of the epitaxial region between a first trench and a second trench is adjacent to a first p-contact and the first surface of the epitaxial region between the third trench and a fourth trench is adjacent to a second p-contact, wherein the first trench, the second trench, the third trench, and the fourth trench are sequential trenches, and wherein the first surface of the epitaxial region is substantially planar; and
a plurality of n-contacts disposed on a second surface of the epitaxial material opposite the first surface, wherein adjacent ones of the plurality of n-contacts are separated by isolation trenches, the isolation trenches extending into the epitaxial material from the second surface of the epitaxial material.

6. The laser device structure of claim 5, further comprising:
an insulating layer overlying the plurality of n-contacts and at least partially filling the isolation trenches; and
metal lines overlying the insulating layer, wherein each metal line contacts one of the n-contacts through a via in the insulating layer.

7. The laser device structure of claim 5, wherein the trenches extend into the at least one active region of the epitaxial region.

8. The laser device structure of claim 5, wherein each of the plurality of p-contacts and associated epitaxial region form an individually addressable emitter.

9. The laser device structure of claim 5, wherein the first trench and the second trench are bounded on the second surface of the epitaxial material by adjacent isolation trenches.

10. The laser device structure of claim 5, wherein one of the isolation trenches on the second surface of the epitaxial material is disposed between the second trench and the third trench.

11. The laser device structure of claim 5, wherein each of the trenches are spatially aligned with an edge of an associated one of the p-contacts.

12. The laser device structure of claim 5, wherein the trenches are partially filled with the bonding material.

13. The laser device structure of claim 5, wherein the first surface of the epitaxial region is planar.

14. The laser device structure of claim 5, wherein a first portion of the epitaxial region between the first trench and the second trench forms a first emitter, and a second portion of the epitaxial region between the third trench and the fourth trench forms a second emitter.

15. The laser device structure of claim 5, wherein each of the plurality of p-contacts is immediately adjacent to the bonding material.

16. The laser device structure of claim 5, wherein each of the plurality of n-contacts is immediately adjacent to an insulating layer.

17. The laser device structure of claim 5, further comprising:
an insulating layer overlying the plurality of n-contacts and at least partially filling the isolation trenches; and
a metal ground plate extending over the insulating layer, wherein the metal ground plate is coupled to a ground plane that provides electrical coupling to the plurality of p-contacts.

18. The laser device structure of claim 5, further comprising:
a first insulating layer overlying the plurality of n-contacts and at least partially filling the isolation trenches;
metal lines overlying the first insulating layer, wherein each metal line contacts one of the n-contacts through a via in the first insulating layer;
a second insulating layer overlying the first insulating layer so that the metal lines extend between the first insulating layer and the second insulating layer; and
an electrically conductive ground plate extending over the second insulating layer.

19. The laser device structure of claim 18, further comprising an electrically conductive ground plane coupled to the plurality of p-contacts, wherein the electrically conductive ground plane is coupled to the electrically conductive ground plate.

20. A micro-display using electromagnetic radiation generated by the laser device structure of claim 5.
